(19) United States
(12) Patent Application Publication
(10) Pub. No.: US 2025/0349591 A1
(43) Pub. Date: Nov. 13, 2025

(54) FACILITATING WAFER DEBONDING BY INTRODUCING MOISTURE TO BONDING INTERFACE

(71) Applicant: Micron Technology, Inc., Boise, ID (US)

(72) Inventors: Kyle K. Kirby, Eagle, ID (US); Andrew M. Bayless, Boise, ID (US); Kunal R. Parekh, Boise, ID (US)

(21) Appl. No.: 19/199,382

(22) Filed: May 6, 2025

Related U.S. Application Data
(60) Provisional application No. 63/644,392, filed on May 8, 2024.

(51) Int. Cl. H01L 21/683

(52) U.S. Cl. CPC H01L 21/6835; H01L 2221/68345; H01L 2221/68381

(57) ABSTRACT

A semiconductor wafer including a first dielectric layer disposed on top of the semiconductor wafer, the first dielectric layer having a first frontside surface, a second dielectric layer embedded in the first dielectric layer, the second dielectric layer containing moisture and having a second frontside surface horizontally aligned with the first frontside surface, and oxygen covalent dangling bonds and hydroxide dangling bonds disposed on the first frontside surface and the second frontside surface. Another semiconductor wafer including a first dielectric layer disposed on top of the semiconductor wafer, the first dielectric layer having a frontside surface, a second dielectric layer disposed underneath the first dielectric layer, the second dielectric layer containing moisture, and oxygen covalent dangling bonds and hydroxide dangling bonds disposed on the frontside surface.

### CROSS-REFERENCE TO RELATED APPLICATION(S)

The present application claims priority to U.S. Provisional Patent Application No. 63/644,392, filed May 8, 2024, the disclosure of which is incorporated herein by reference in its entirety.

### TECHNICAL FIELD

The present disclosure generally relates to semiconductor wafer bonding and more particularly relates to facilitating semiconductor wafer debonding through introducing moisture to the bonding interface.

### BACKGROUND

Semiconductor wafers bonding and debonding are foundational technologies in modern semiconductor fabrication, enabling the creation of advanced semiconductor assembly and devices with improved performance, reduced size, and new functionalities. During a wafer bonding process, two or more semiconductor wafers are joined together using various bonding techniques such as fusion bonding, adhesive bonding, and others. Debonding is a process of separating bonded wafers after necessary processing has been completed. Various techniques including mechanical debonding, thermal slide debonding, and laser debonding can be adopted to physically separate the wafers. Often time the wafer debonding process can be challenging, especially in temporary bonding applications where a carrier wafer needs to be removed.

### BRIEF DESCRIPTION OF THE DRAWINGS

FIGS. 1A and 1B illustrate example semiconductor wafers configured to facilitate semiconductor wafer debonding in accordance with an embodiment of the present technology.

FIGS. 2A to 2D illustrate a flow of fabricating an example semiconductor wafer having a patterned surface structure in accordance with an embodiment of the present technology.

FIGS. 3A to 3D illustrate a flow of bonding and debonding semiconductor wafers utilizing the example semiconductor wafer having a patterned surface structure in accordance with an embodiment of the present technology.

FIGS. 4A to 4C illustrate a flow of fabricating another example semiconductor wafer having a stacked surface structure configured to facilitate semiconductor wafer debonding in accordance with an embodiment of the present technology.

FIGS. 5A to 5D illustrate a flow of bonding and debonding semiconductor wafers utilizing the example semiconductor wafer having a stacked surface structure in accordance with an embodiment of the present technology.

FIGS. 6A to 6C illustrate examples of bonded semiconductor wafers having patterned surface structures in accordance with embodiments of the present technology.

FIGS. 7A to 7C illustrate top down views of example semiconductor wafers having various surface structures in accordance with an embodiment of the present technology.

FIG. 8 illustrates a flow chart of a method for bonding and debonding semiconductor wafers in accordance with an embodiment of the present technology.

FIG. 9 illustrates a block diagram of a system that includes a semiconductor device configured in accordance with an embodiment of the present technology.

### DETAILED DESCRIPTION

As an essential step in the fabrication of multi-layer or stacked semiconductor devices, semiconductor wafer debonding process presents several challenges that can impact manufacturing yield, device performance, and reliability. For example, the expansion coefficients of different materials on the bonded semiconductor wafers can vary, leading to thermal stress during the heating and cooling phases. The thermal stress contained in the bonded wafers can cause warping, cracking, or delamination of the materials when separating the wafers. In addition, chemicals used in the wafer debonding process may damage the bonded wafers or device components integrated on the wafers. Finding selective solvents or etchants that can effectively dissolve bonding materials without affecting semiconductor materials can be challenging. Further, certain wafer bonding process may form a strong bonding interface (e.g., with chemical bonds having a high bond energy) between the bonded wafers, making the downstream wafer debonding process extremely hard.

To solve the issued and challenges described above, different semiconductor wafer bonding and debonding methodologies may be needed to detach wafers without damaging their delicate structures or altering their properties. The present technology provides a methodology of weakening bonds at wafer bonding interface using moisture. The moisture can be pre-existed at the wafer bonding interface and activated during the wafer debonding process, so as to convert oxygen covalent bonds to hydroxide bonds which have a lower bond energy. The lower energy bonds converted using moisture at the wafer bonding interface facilitates the wafer debonding process and offer a higher process yield. Various semiconductor wafer surface structures can be adopted in the present technology to store moisture or transfer moisture to the bonding interface during a wafer debonding process. For example, a patterned wafer surface structure can be formed by patterning a moisture rich dielectric film into another continuous dielectric thin film. In another example, a moisture rich dielectric film can be disposed underneath another dielectric layer, on a frontside of a semiconductor wafer. The moisture rich dielectric film can be in various patterns above the semiconductor wafer. In addition, the moisture rich dielectric film extends to the edge of the semiconductor wafer to absorb and transfer moisture from a surrounding environment to the wafer bonding interface.

The present technique can be adopted to fabricate an electronic device architecture that incorporates an engineered semiconductor wafer. This wafer can form a substrate upon which a first dielectric layer is deposited. The first dielectric layer has a first frontside surface that is exposed and tailored for subsequent layering or processing. Within the body of this first dielectric layer, a second dielectric layer can be embedded. This second dielectric layer is distinct in its composition and moisture-rich, e.g., having a moisture ranging between 1% and 3%. In some other example, the second dielectric layer contains moisture higher than 3%. In the electronic device, the second dielectric layer is also designed to have a second frontside surface that is horizontally aligned with the first frontside surface of the first dielectric layer, ensuring a uniform topography and facilitating the integration of additional device components. Both the first and second frontside surfaces are treated to possess oxygen covalent dangling bonds and hydroxide dangling bonds.

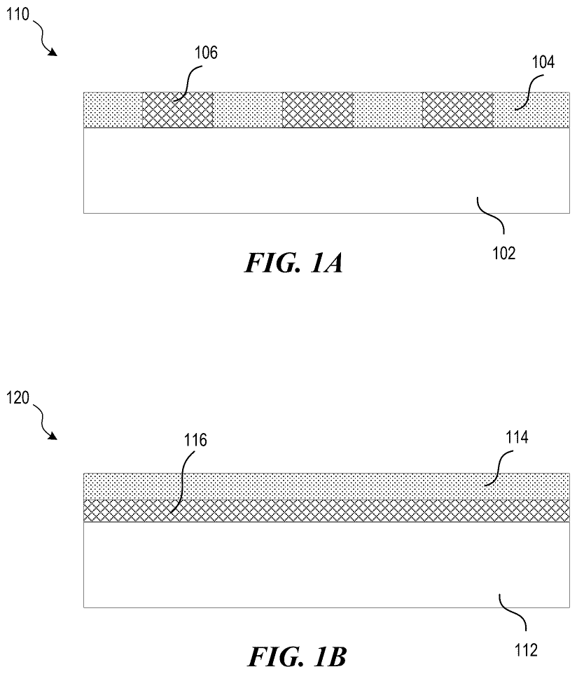

FIGS. 1A and 1B illustrate semiconductor wafers 110 and 120 that have surface structures configured to facilitate semiconductor wafer debonding in accordance with an embodiment of the present technology. For example, FIG. 1A discloses a cross sectional view of semiconductor wafer 110 having patterned surface structure. As shown, the semiconductor wafer 110 includes a substrate 102 and dielectric layers 104 and 106 disposed above a frontside surface of the substrate 102. In one aspect, the dielectric layers 104 and 106 may form as interfacing surface, and there may be other dielectric layers underneath these dielectric layers 104 and 106. In this example, the dielectric layer 104 can be a continuous layer deposited on the substrate 102, and dielectric layer 106 can be embedded in the dielectric layer 104 using photolithography and patterning technologies. Here, a first frontside surface of the dielectric layer 104 and a second frontside surface of the dielectric layer 106 can be coplanar. In particular, a chemical mechanical polishing process can be conducted on the semiconductor wafer 110 after the dielectric layer 106 is deposited thereon, making the first frontside surface and the second frontside surface horizontally aligned.

In this example, the dielectric layer 104 can be made of materials including silicon dioxide (SiO₂), silicon nitride (Si₃N₄), aluminum oxide (Al₂O₃), hafnium oxide (HfO₂) titanium dioxide (TiO₂), low-K dielectric materials, and/or a combination thereof. Chemical bonds present at the first frontside surface of the dielectric layer 104 include silicon—oxygen—silicon bonds, within which each silicon atom is typically tetrahedrally coordinated with four oxygen atoms and form a three dimensional network. These bonds are covalent and relatively strong in providing a structural integrity in the dielectric layer 104. In addition, the first frontside surface of the dielectric layer 104 may not be defect free and include oxide covalent dangling bonds thereon. For example, when an atom at the first frontside surface of the dielectric layer 104 has valence electrons that are not engaged in bonding, the oxide covalent dangling bonds occur. In this structure, covalent dangling bonds are present within and on the frontside surface of the dielectric layer 104, and these bonds orient themselves away from the underlying substrate 102. These dangling bonds are characterized by their unpaired electrons (e.g., at the terminal atoms of the silicon dioxide matrix), which are not fully engaged in bonding as they would be in a perfect lattice structure.

In this example, the dielectric layer 106 can be made of materials including tetraethyl orthosilicate (TEOS), silicon carbon nitride (SiCN), or a combination there of. Moisture can be presented in the dielectric layer 106 due to various factors including the ambient humidity during the deposition of the dielectric layer 106, the inherent porosity of the dielectric layer 106 allowing water ingress, or residual moisture from the dielectric layer 106 deposition process itself. Here, the dielectric layer 106 may have a moderate moisture content, e.g., a moisture content (weight percentage) ranging between 1% and 3%. In some other examples, the dielectric layer 106 may have a high moisture content, e.g., a moisture content higher than 3%.

Chemical bonds present at the first frontside surface of the dielectric layer 106 may include silicon—oxygen—silicon covalent bonds, silicon—hydroxyl (OH) bonds, hydrogen bonds, and hydroxide (OH) dangling bonds. The silicon—OH bonds can be formed when some of the Si—O bonds are terminated in OH rather than another silicon atom, leading to a formation of Si—OH groups. A density of a specific type of chemical bonds such as the hydroxide dangling bonds, in comparison to other chemical bonds such as the silicon—oxygen—silicon bonds, can be adjusted by manipulating dielectric layer 106 deposition parameters. For example, using a chemical vapor deposition (CVD) process with a controlled rate of hydrolysis and partial condensation could increase a likelihood of OH-rich surface of the dielectric layer 106. In addition, increasing the ambient humidity during or after deposition can also promote the hydrolysis of a TEOS thin film and the formation of Si—OH groups.

As shown in FIG. 1A, a frontside surface of the semiconductor wafer 110 contains chemical bonds from the first frontside surface of the dielectric layer 104 and the second frontside surface of the dielectric layer 106. The ratio or density of various chemical bonds on the frontside surface of the semiconductor wafer 110 may also relates to a surface ratio or a volume ratio of the dielectric layer 106 to the dielectric layer 104. In this example, each of the dielectric layer 104 and the dielectric layer 106 has a thickness ranging from 10 nm to 500 μm. Specifically, the dielectric layer 106 may have a thickness less than the dielectric layer 104.

FIG. 1B discloses a cross section view of another semiconductor wafer 120 having stacked surface structure. As shown, the semiconductor wafer 120 includes a substrate 112 and dielectric layers 114 and 116 that are sequentially stacked thereon. In this example, the dielectric layer 114 can be made of materials including silicon dioxide (SiO₂), silicon nitride (Si₃N₄), aluminum oxide (Al₂O₃), hafnium oxide (HfO₂) titanium dioxide (TiO₂), low-K dielectric materials, and/or a combination thereof. Additionally, chemical bonds present at the frontside surface of the dielectric layer 114 may include silicon—oxygen—silicon bonds as well as oxide covalent dangling bonds. Moreover, hydroxide dangling bonds contributed from the dielectric layer 116 may also exist at the frontside surface of the dielectric layer 114. Here, the dielectric layer 114 may have a thickness ranging from 10 nm to 500 μm.

In the semiconductor wafer 120, the dielectric layer 116 is disposed under the dielectric layer 114. The dielectric layer 116 can be made of materials including TEOS, SiCN, and/or a combination thereof. In this example, moisture can be presented in the dielectric layer 116 due to various factors including the ambient humidity during the deposition of the dielectric layer 116, the inherent porosity of the dielectric layer 116 allowing water ingress, or residual moisture from the dielectric layer 116 deposition process itself. Specifically, moisture can be transferred from the dielectric layer 116 to the dielectric layer 114 and form hydroxide dangling bonds in the dielectric layer 114. Because the hydroxide dangling bonds in the dielectric layer 114 are related to moisture contained in or transferred from the dielectric layer 116, a first ratio of a density of the oxygen covalent dangling bonds to a density of the hydroxide dangling bonds can be proportional to a second ratio of the thickness of the dielectric layer 114 to the thickness of the dielectric layer 116. Here, the dielectric layer 114 may have a thickness ranging from 100 nm to 10 μm. In some other examples, the dielectric layer 116 can be embedded in the dielectric layer 114, e.g., having their bottom surfaces coplanar above the substrate 112.

In this example, the semiconductor wafers 110 and 120 can be carrier wafers facilitating semiconductor device wafer or product wafer processing. For example, each of the semiconductor wafers 110 and 120 can provide a stable and robust platform onto which a device wafer can be temporarily bonded, allowing for subsequent processing steps without risk of damages. Additionally, each of the semiconductor wafers 110 and 120 is suitable for specific bonding techniques including adhesive bonding, fusion bonding, eutectic bonding, and/or another method. The surface of each of the semiconductor wafers 110 and 120 is flat and chemically compatible to ensure a strong and reliable bond with the device wafer. Moreover, the semiconductor wafers 110 and 120, as carrier wafers, are also reusable. They can withstand wafer debonding process and then be cleaned and re-prepared for subsequent use. With the specific designed wafer surface structure, e.g., the patterned surface structure in FIG. 1A and stacked surface structure in FIG. 1B, the semiconductor wafers 110 and 120 can facilitate wafer debonding process through introducing moisture to the wafer bonding interface and weakening the bonds formed between bonded semiconductor wafers.

In some other examples, the semiconductor wafers 110 and 120 can be device wafers. For example, each of the substrate 102 of the semiconductor wafer 110 and the substrate 112 of the semiconductor wafer 120 may include device structures such as transistors, passive components, and/or electrical interconnections. The patterned surface structure in semiconductor wafer 110 and stacked surface structure in semiconductor wafer 120 can facilitate separating the device wafers from other semiconductor wafers in a wafer debonding process. In some examples, the one or more device structures are formed on the surface of the substrate 102 closer to the dielectric layers 104 and 106. In some alternative examples, the one or more device structures are formed on the surface that is opposite the dielectric layers 104 and 106.

The semiconductor wafers 110 and 120 illustrates in FIGS. 1A and 1B may also include metal pads (not shown). For example, metal pads can be disposed on the frontside surface of the dielectric layers 104 and 106 in semiconductor wafer 110, or on the frontside surface of the dielectric layer 114 in semiconductor wafer 120. The metal pads can facilitate forming metal-metal bonds during a semiconductor wafer bonding process such as fusion bonding.

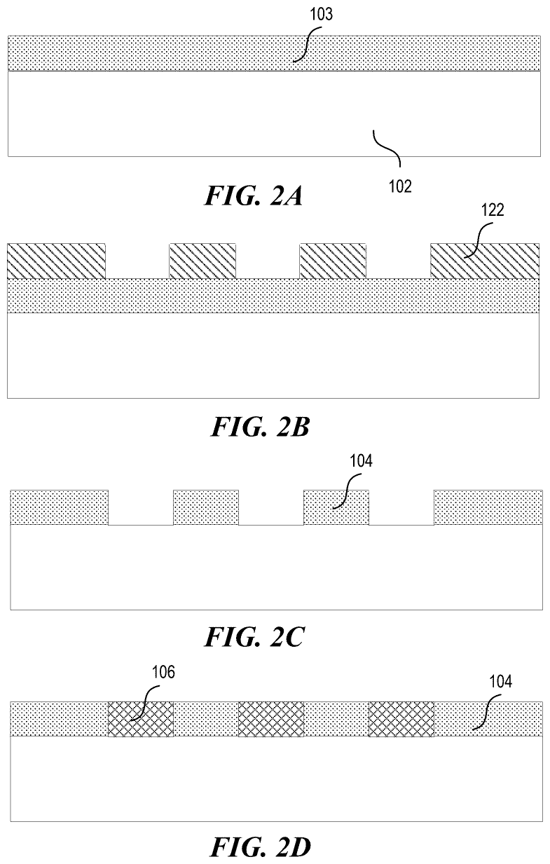

FIGS. 2A to 2D illustrates a flow of fabricating the example semiconductor wafer 110 having the patterned surface structure in accordance with an embodiment of the present technology. This flow starts from deposition a continuous dielectric layer 103 on the frontside surface of the substrate 102. The continuously coated dielectric layer 103 is made of a same material to the patterned dielectric layer 104 described in FIG. 1A. Specifically, the dielectric layer 103 can be deposited using a thin film deposition technique such as chemical vapor deposition (CVD) technique, physical vapor deposition (PVD) technique, atomic layer deposition (ALD) technique, and/or other processes that are proper in the flow. Here, the dielectric layer 103 may have a thickness ranging from 10 nm to 500 μm.

FIG. 2B discloses that a hard mask layer 122 can be patterned above the dielectric layer 103. The patterned hard mask structure can be formed by depositing a continuous hard mask layer and then patterning the hard mask layer using photolithography techniques and etching techniques such as wet etching and/or dry plasma etching techniques. Once the patterned hard mask is ready, another etching process such as an isotropic etching process (e.g., wet chemical etching) or an anisotropic etching process (e.g., reactive ion etching (RIE)) can be conducted to remove materials of the dielectric layer 103 from exposed hard mask regions. As shown in FIG. 2C, the dielectric layer 103 can be etched through its thickness and form the patterned dielectric layer 104. In some other examples, the dielectric layer 103 may not be fully etched along its thickness direction. For example, a time controlled etching process can be utilized to partially remove materials (e.g., 50% material removal along the thickness direction) from the dielectric layer 103 through exposed hard mask regions.

FIG. 2D illustrates that the dielectric layer 106 can be deposited into the patterned dielectric layer 104. The dielectric layer 106 may be overgrowth above the frontside surface of the dielectric layer 104, which can be further planarized using a chemical mechanical polishing (CMP) process. As shown in FIG. 2D, the dielectric layers 104 and 106 have frontside surfaces that are coplanar. As described earlier, the dielectric layer 106 can be TEOS or SiCN and contains moisture. Thin film deposition techniques including CVD technique and plasma-enhanced chemical vapor deposition (PECVD) technique can be used to deposit the dielectric layer 106. During the deposition, it is critical to control the moisture content in the deposited film. Process parameters such as temperature, pressure, and gas flow rates can be adjusted to incorporate hydroxyl groups (OH) into the dielectric layer 106 to achieve a desired moisture content. In addition, post deposition thermal treatment such as thermal annealing can also be controlled to drive out residual moisture and reduce hydroxyl content therein.

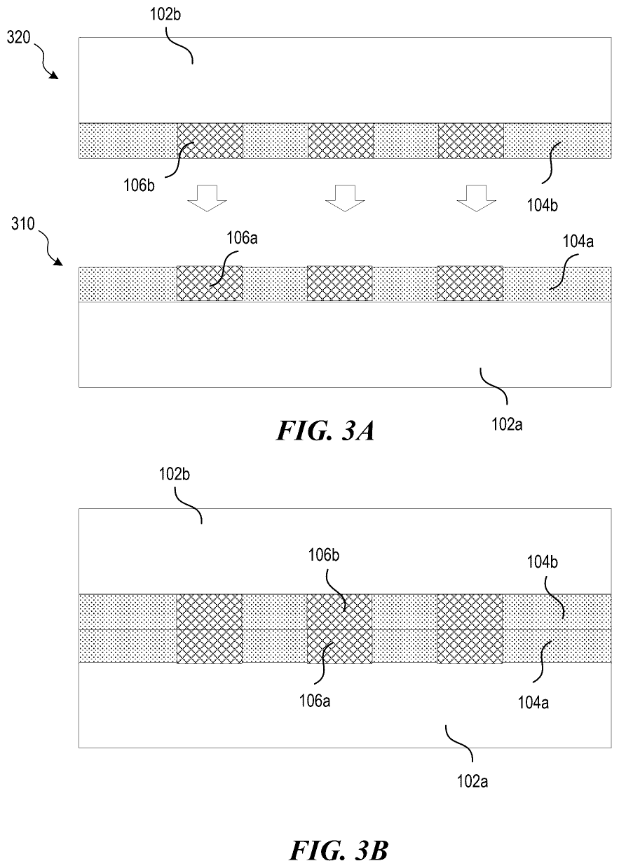

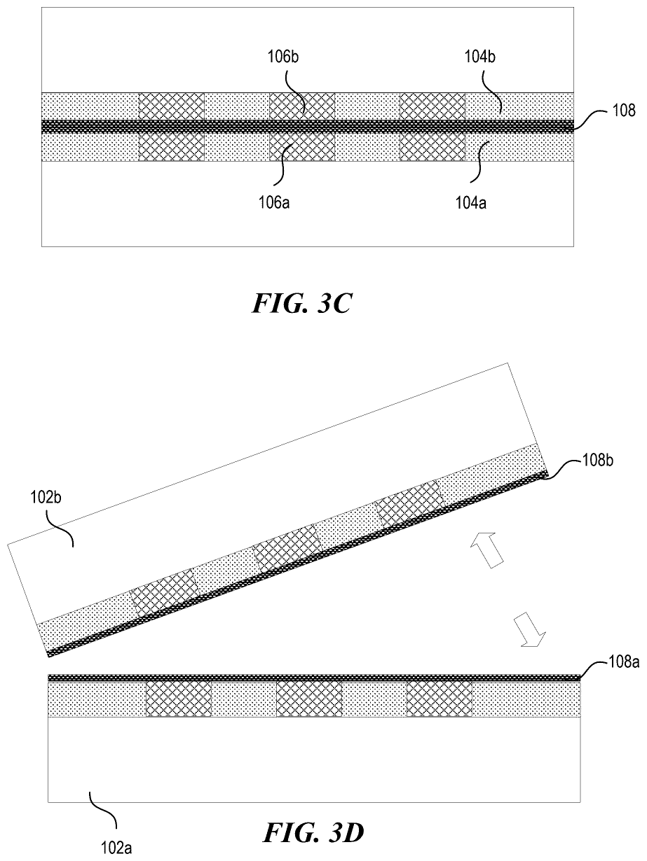

FIGS. 3A to 3D illustrate a flow of bonding and debonding semiconductor wafers utilizing the example semiconductor wafer 110 having a patterned surface structure in accordance with an embodiment of the present technology. In this example, a semiconductor device wafer 320 is bonded to a carrier wafer 310. After certain semiconductor manufacturing processes, the semiconductor device wafer 320 and the carrier wafer 310 are debonded from each other.

In this example, both of the semiconductor device wafer 320 and the carrier wafer 310 have the patterned surface structure described in FIG. 1A. The patterned surface structure of the semiconductor device wafer 320 and the carrier wafer 310 can be processed following a flow similar to the one described in FIGS. 2A to 2D. In addition, the dielectric layers 104a and 104b can be made of materials similar to the dielectric layer 104 described in FIG. 1A. Further, the dielectric layers 106a and 106b can contain moisture and made of materials similar to the dielectric layer 106 of FIG. 1A. Here, the semiconductor device wafer 320 and the carrier wafer 310 can be bonded using a hybrid bonding (also refers as fusion bonding or direct bonding) process, by facing the frontside of the semiconductor device wafer 320 to the frontside surface of the carrier wafer 310. Here, the fusion bonding between the semiconductor device wafer 320 and the carrier wafer 310 may be formed at a temperature close to 300° C. or above and/or with compression pressures.

As shown in FIG. 3B, the dielectric layers 104b and dielectric layers 106b of the semiconductor device wafer 320 can be respectively aligned to the dielectric layers 104a and dielectric layers 106a of the carrier wafer 310 for the bonding process. Here, covalent oxygen bonds can be formed between the surfaces of dielectric layers 104a and 104b. In addition, hydroxide (O—H) bonds can be formed between the surfaces of the dielectric layers 106a and 106b. The fusion bonded semiconductor device wafer 320 on the carrier wafer 310 can provide a more rigid mechanical strength during downstream processes. In some other examples, a misalign margin is allowed in the bonding process. Moreover, the dielectric layer 106b of the semiconductor device wafer 320 can be bonded to the dielectric layer 104a of the carrier wafer. Additionally, the dielectric layer 104b of the semiconductor device wafer 320 can be bonded to the dielectric layer 106a of the carrier wafer. Covalent oxygen bonds and hydroxide (O—H) bonds can be formed at the interface between the dielectric layer 106b and dielectric layers 104a and the interface between the dielectric layer 104b and dielectric layers 106a.

FIG. 3C illustrates a weakened bonding interface 108 between the semiconductor device wafer 320 and carrier wafer 310. The weakened bonding interface 108 may contain more hydroxide (O—H) bonds in comparison to the as-bonded interface of FIG. 3B. The additional hydroxide (O—H) bonds at the bonding interface may be introduced from the dielectric layers 106a and 106b which contain moisture. In addition, at least one of the dielectric layers 106a and 106b can be extended to an edge of the corresponding wafer, and extra moisture can be introduced to the bonding interface through the at least one of the dielectric layers 106a and 106b. During this process, a high process temperature (e.g., 300° C.-500° C.) can be applied to activate the moisture contained in the dielectric layers 106a and 106b. The moisture can be re-introduced to the bonding interface. Moreover, the moisture can react with oxygen covalent bonds disposed at the bonding interface and convert it to hydroxide (O—H) bonds (e.g., through a chemical reaction O₂—+H₂O→OH—+OH—). In this example, the bonding interface 108 is weaker than as-bonded interface because it contains a higher density of hydroxide (O—H) bonds, which have a lower bond energy compared to oxygen covalent bonds.

In some examples, additional semiconductor wafers can be further stacked on the semiconductor device wafer 320, after the semiconductor device wafer 320 is bonded to the carrier wafer 310 as described in FIG. 3C. Specifically, the substrate 102b of the semiconductor device wafer 320 can be thinned front its backside, e.g., using wafer grinding processes such as a mechanical grinding process and/or a CMP process. After that, an additional semiconductor wafer can be bonded to the thinned semiconductor device wafer 320, e.g., through bonding a frontside surface of the additional semiconductor wafer to the backside surface of the semiconductor device wafer 320 to form a front to back (F2B) bonding interface therebetween. These processes can be repeated multiple times to form a stacked semiconductor device layers above the bonding interface 108.

In this example, the semiconductor device wafer 320 and the carrier wafer 310 can be debonded after forming the weakened bonding interface 108. As shown in FIG. 3D, the debonding can be done through the weakened bonding interface 108. A mechanical debonding process can be conducted by inserting a blade or a wedge at the wafer edge and applying mechanical stress. In addition, a laser debonding can be conducted using a laser to dissolve the weakened bonding interface 108. The laser can be directed at the weakened bonding interface 108 or around edges of the semiconductor device wafer 320 and carrier wafer 310, causing the bonding interface to decompose, e.g., breaking the hydroxide ionic bonds at the weakened bonding interface 108. In this example, some other debonding process such as chemical debonding, thermal debonding, and/or UV release debonding can also be applied. The weakened bonding interface 108 facilitates a relative easier debonding process because it requires lower debond forces, therefore providing a higher debonding process yield. After the debonding process, residual weakened interface layer 108a and 108b can be removed using a wet chemical cleaning process or a CMP process. Further, the carrier wafer 310 can be reused in another wafer bonding process. In some examples, the debonded semiconductor device wafer 320 may include a stack of semiconductor device layers with multiple permanent bonded interfaces disclose therebetween.

In some other examples, the patterned surface structure can exist in only one of the semiconductor device wafer 320 and the carrier wafer 310. For example, the carrier wafer 310 is fabricated as described in FIG. 3A, and the semiconductor device wafer 320 only has the dielectric layer 104b deposited on its frontside surface. In this condition, a fusion bonding interface can be formed between the dielectric layer 104b and the dielectric layers 104a and 106a. Additionally, the bonding interface can be further weakened, similar to the process described in FIG. 3C, by chemical reactions caused by moisture contained and transferred through the dielectric layer 106a of the carrier wafer 310.

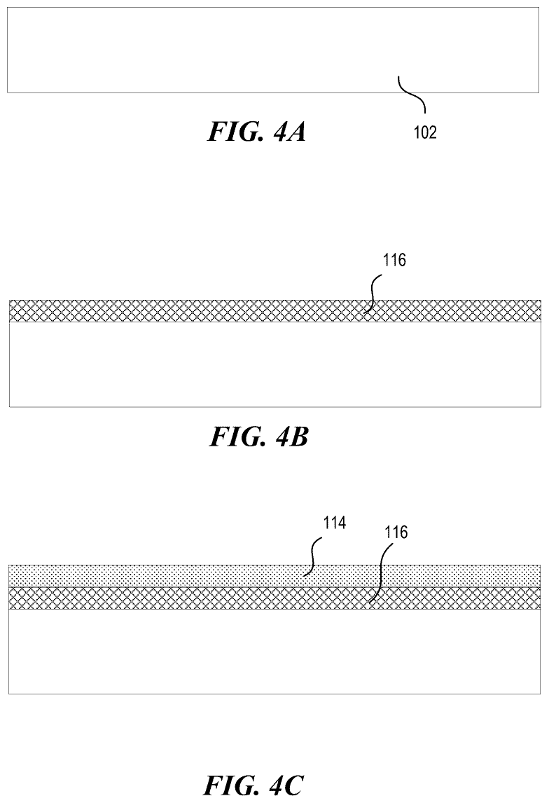

FIGS. 4A to 4C illustrates a flow of fabricating the example semiconductor wafer 120 having a stacked surface structure in accordance with an embodiment of the present technology. In this example, the dielectric layer 116 can be continuously deposited on the frontside surface of the substrate 102. Thin film deposition techniques such as CVD, PVD, and/or ALD processes can be used to fabricate the dielectric layer 116. Here, the dielectric layer 116 may contain moisture and have a thickness ranging from 100 nm to 10 μm. To control the moisture content to a desired level, process parameters including reaction gas flow, chamber humidity, and wafer vapor introduction can be modified during the deposition of the dielectric layer 116. In a next step shown in FIG. 4C, the dielectric layer 114 can be deposited above the dielectric layer 114. Similarly, the dielectric layer 114 can be deposited using thin film deposition techniques including CVD, PVD, and/or ALD processes. The dielectric layer 114 has a flat frontside surface and has a thickness ranging from 100 nm to 500 μm.

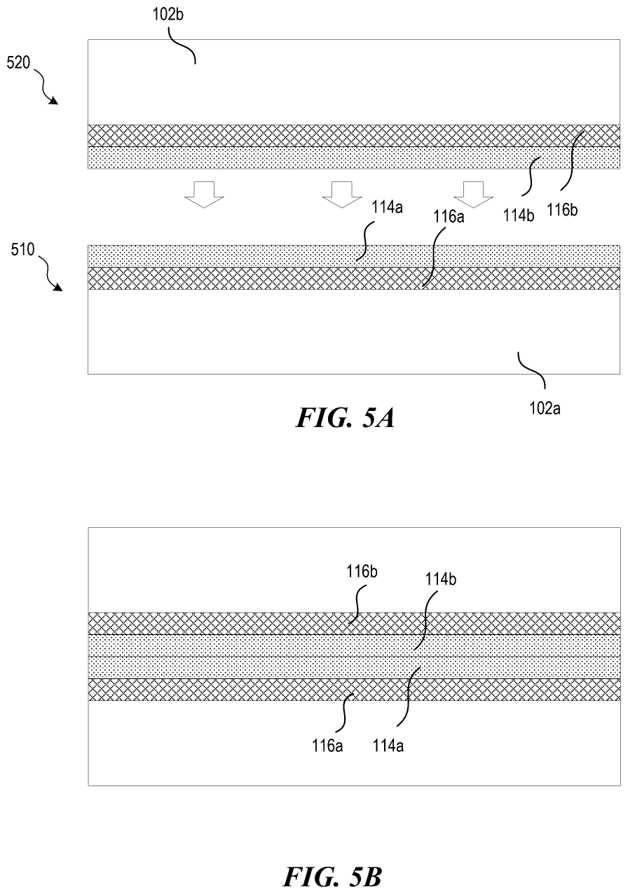

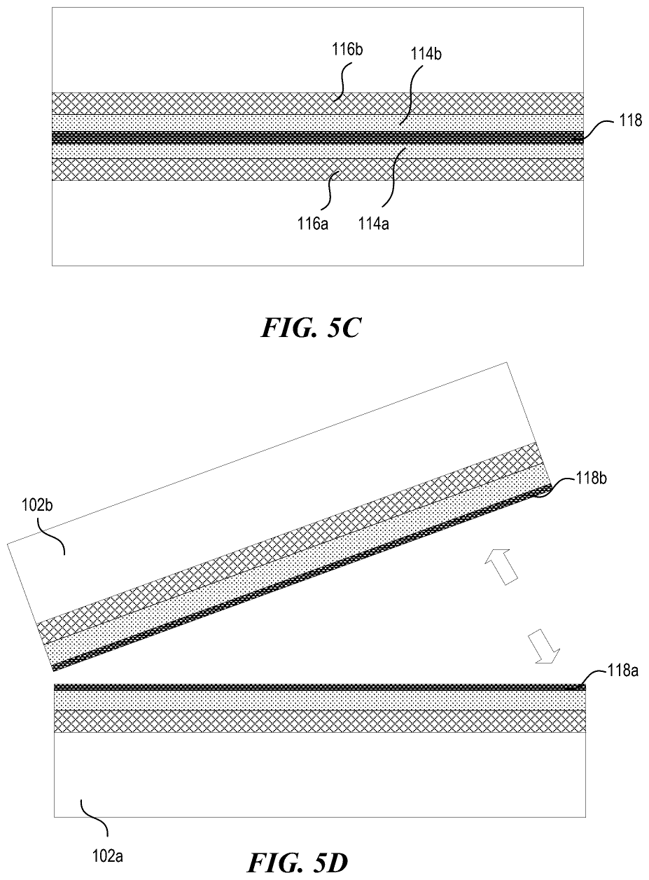

FIGS. 5A to 5D illustrate a flow of bonding and debonding semiconductor wafers utilizing the example semiconductor wafer 120 having the stacked surface structure in accordance with an embodiment of the present technology. In this example, a semiconductor device wafer 520 is bonded to a carrier wafer 510. After certain semiconductor manufacturing processes, the semiconductor device wafer 520 and the carrier wafer 510 are debonded from each other.

In this example, both of the semiconductor device wafer 520 and the carrier wafer 510 have the patterned surface structure described in FIG. 1B. The patterned surface structure of the semiconductor device wafer 520 and the carrier wafer 510 can be processed following a flow similar to the one described in FIGS. 4A to 4C. In addition, the dielectric layers 114a and 114b can be made of materials similar to the dielectric layer 104 described in FIG. 1A. Further, the dielectric layers 116a and 116b can contain moisture and made of materials similar to the dielectric layer 116 of FIG. 1B. As shown in FIG. 5A, the semiconductor device wafer 520 and the carrier wafer 510 can be bonded using a hybrid bonding process, by facing the dielectric layer 114b of the semiconductor device wafer 520 to the dielectric layer 114a of the carrier wafer 510.

As shown in FIG. 5B, the dielectric layers 114b and 114a can be bonded at the interface between the semiconductor device wafer 520 and the carrier wafer 510. Here, covalent oxygen bonds as well as hydroxide (O—H) bonds can be formed at the bonding interface. In addition, the covalent oxygen bonds may have a higher density in comparison to the hydroxide (O—H) bonds.

In next process step, a weakened bonding interface 118 can be formed at the bonding interface between the semiconductor device wafer 520 and carrier wafer 3510. The weakened bonding interface 118 may contain more hydroxide (O—H) bonds in comparison to the as-bonded interface of FIG. 5B. The additional hydroxide (O—H) bonds at the bonding interface may be caused by moisture introduced from underneath dielectric layers 116a and 116b. In addition, at least one of the dielectric layers 116a and 116b can be extended to an edge of the corresponding wafer, and extra moisture can be introduced to the bonding interface through the at least one of the dielectric layers 116a and 116b. Here, moisture exists at the bonding interface can react with oxygen covalent bonds and convert it to hydroxide (O—H) bonds (e.g., through the chemical reaction O₂—+H₂O→OH—+OH—). Similar to the weakened bonding interface 108, the bonding interface 118 in this example is weaker than as-bonded interface as it contains a higher density of hydroxide (O—H) bonds, which have a lower bond energy compared to oxygen covalent bonds.

In some examples, additional semiconductor wafers can be further stacked on the semiconductor device wafer 520, after the semiconductor device wafer 520 is bonded to the carrier wafer 510 as described in FIG. 5C. Specifically, the substrate 102b of the semiconductor device wafer 520 can be thinned front its backside, e.g., using wafer grinding processes such as the mechanical grinding process and/or the CMP process. After that, an additional semiconductor wafer can be bonded to the thinned semiconductor device wafer 520, e.g., through bonding a frontside surface of the additional semiconductor wafer to the backside surface of the semiconductor device wafer 520 to form a F2B bonding interface therebetween. These processes can be repeated multiple times to form a stacked semiconductor device layers above the bonding interface 118.

In a debond process illustrate in FIG. 5D, the semiconductor device wafer 520 can be detached from the carrier wafer 510. Various debonding techniques such as mechanical debonding, laser debonding, chemical debonding, thermal debonding, and/or UV release debonding can be used in this process to break the hydroxide ionic bonds at the weakened bonding interface 118. The weakened bonding interface 118 in this example would facilitate the wafer debonding process because it requires a lower debond force to detach the semiconductor device wafer 520 from the carrier wafer 510, achieving a higher debonding process yield. After the debonding process, residual weakened interface layer 118a and 118b can be removed using a wet chemical cleaning process or a CMP process. Further, the carrier wafer 510 can be reused in another wafer bonding process. In some examples, the debonded semiconductor device wafer 520 may include a stack of semiconductor device layers with multiple permanent bonded interfaces disclose therebetween.

In some other examples, the stacked surface structure can exist in only one of the semiconductor device wafer 520 and the carrier wafer 510. For example, the carrier wafer 510 can be fabricated as described in FIG. 5A, and the semiconductor device wafer 520 can be processed to only contain the dielectric layer 114b above its substrate 102b. In this condition, a fusion bonding interface can be formed between the dielectric layers 114b and 114a. In this example, the bonding interface can be further weakened, similar to the process described in FIG. 5C, by chemical reactions caused by moisture contained and transferred through the dielectric layer 116a of the carrier wafer 510.

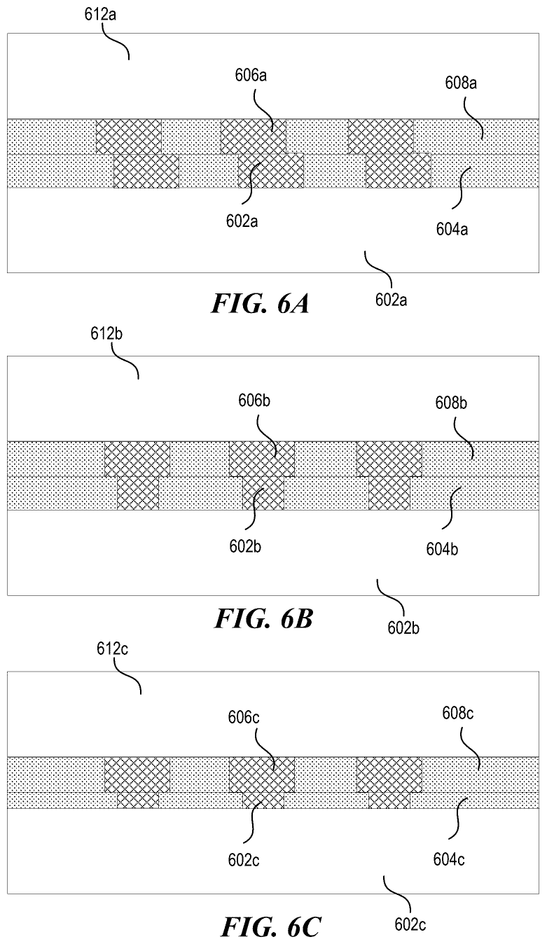

The present technology provides process margins in semiconductor wafers bonding and debonding processes. For example, FIGS. 6A to 6C illustrate examples of bonded semiconductor wafers having patterned surface structures in accordance with embodiments of the present technology. FIG. 6A shows bonded semiconductor wafers, each of the semiconductor wafers having the patterned surface structure described in FIGS. 1A. For example, a carrier wafer including dielectric layers 602a and 604a is bonded with a device wafer including dielectric layers 606a and 608a. The dielectric layers 606a and 602a can be made of materials similar to the dielectric layer 106 and contain moisture. In this example, the dielectric layer 602a is not accurately aligned to the dielectric layers 606a, with a misalignment close to 25% of its width. In some other examples, the dielectric layer 602a of the carrier wafer can be completely offset from corresponding dielectric layer 606a of the device wafer.

In another example, the patterned surface structure can vary between the bonded semiconductor device wafer and the carrier wafer. For example, FIG. 6B shows a device wafer including a dielectric layer 606b and a carrier wafer including a dielectric layer 602b. The dielectric layers 606b and 602b can be made of materials similar to the dielectric layer 106 and contain moisture. In this example, the width of each of the patterned dielectric layer 602b can be smaller than corresponding dielectric layer 606b. In another example, FIG. 6C shows a device wafer including a patterned surface layer structure thinner than that of a corresponding semiconductor device wafer. Here, the dielectric layers 602c and 604c of the carrier wafer can be thinner than the dielectric layers 606c and 608c of the semiconductor device wafer.

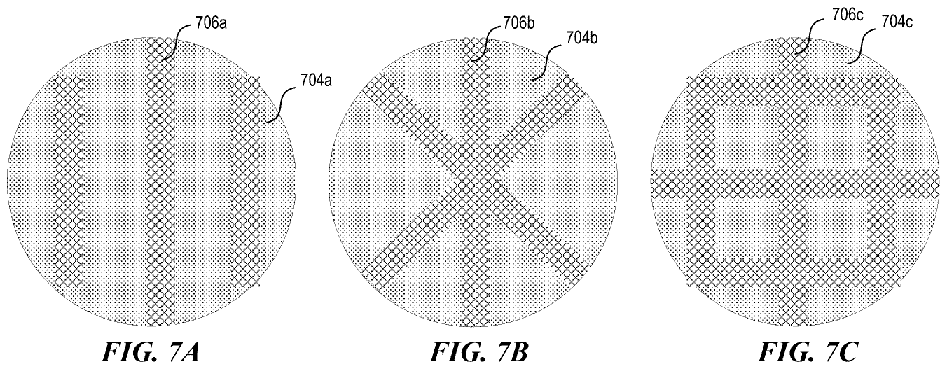

In the present technology, the dielectric layers of a semiconductor device wafer or a carrier that contains moisture can be processed in various patterns, in order to facilitate the wafer bonding and debonding processes. For example, FIGS. 7A to 7C illustrate top down views of example semiconductor wafers having different patterned surface structures in accordance with embodiments of the present technology. FIG. 7A shows dielectric layer 706a as stripe lines aligned in parallel. Each of the dielectric layer 706 stripe lines may have a width ranging from 1 μm to 5 cm and extends to the edge of corresponding wafer. In addition, FIG. 7B shows that the dielectric layer 706b can be in a shape of cross over strip lines. As shown, the strip lines can be central divergence to the edge of the semiconductor wafer. In addition, FIG. 7C shows that the dielectric layer 706c can be in a checkboard pattern, within which strip lines extend to the edge of the semiconductor wafer. In the present technology, the dielectric layers 706a, 706b, and 706c can be respectively deposited into patterned dielectric layers 704a, 704b, and 704c, and to form the patterns illustrated in FIGS. 7A to 7C. In these examples, the dielectric layers 706a, 706b, and 706c can absorb or transfer moisture from a surrounding environment.

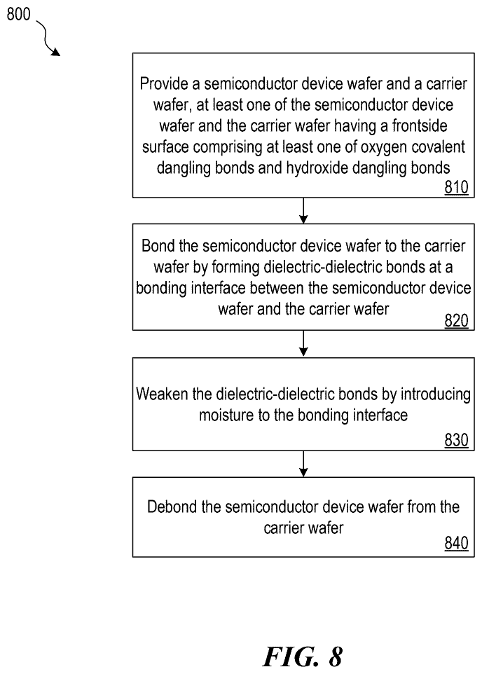

FIG. 8 illustrates a flow chart of a method 800 for debonding semiconductor wafers in accordance with an embodiment of the present technology. The method 800 includes providing a semiconductor device wafer and a carrier wafer, at least one of the semiconductor device wafer and the carrier wafer having a frontside surface comprising at least one of oxygen covalent dangling bonds and hydroxide dangling bonds, at 810. For example, semiconductor device wafer 320 having dielectric layers 104b and 106b and carrier wafer 310 having dielectric layers 104a and 106a can be provided for the bonding and debonding process. Each of the dielectric layers 104a and 104b can be made of SiO₂ and contains oxygen covalent dangling bonds on its frontside surface. In addition, each of the dielectric layers 106a and 106b can contain moisture and includes hydroxide dangling bonds on its frontside surface.

The method 800 also includes bonding the semiconductor device wafer to the carrier wafer by forming dielectric-dielectric bonds at a bonding interface between the semiconductor device wafer and the carrier wafer, at 820. For example, the semiconductor device wafer 320 can be bonded on the carrier wafer 310 using a fusion bonding process. Dielectric-dielectric bonds such as oxygen covalent bonds and hydroxide (O—H) bonds can be formed at the bonding interface.

In addition, the method 800 includes weakening the dielectric-dielectric bonds by introducing moisture to the bonding interface, at 830. For example, a high process temperature (e.g., ranging between 300° C.-500° C.) can be applied to the bonded wafers. The high process temperature can promote a transition of moisture from the dielectric layers 106a and 106b to the bonding interface. Alternatively, a moisture rich environment can be applied to the bonded wafer, and moisture can be transferred to the bonding interface through the dielectric layers 106a and 106b. The moisture could at least partially convert the oxygen covalent bonds to hydroxide (O—H) bonds and reduce the bonding energy at the bonding interface.

Lastly, the method 800 includes debonding the semiconductor device wafer from the carrier wafer, at 840. For example, various debonding processes such as mechanical debonding, laser debonding, chemical debonding, thermal debonding, and/or UV release debonding can be used to detach the semiconductor device wafer 320 from the carrier wafer 310. In this example, the weakened bonding interface 118 would facilitate the wafer debonding process as it requires a lower debond force to separate the wafers, therefore achieving a higher debonding process yield.

Any one of the semiconductor devices and semiconductor device assemblies described above with reference to FIGS. 1 to 8 pertains to the field of semiconductor device fabrication and, more specifically, to a novel technique that significantly enhances the efficiency and reliability of bonding processes used in the assembly of integrated circuits. This technique is particularly applicable to the bonding of chiplets within systems-in-package (SiP), which is a critical step in the creation of compact and high-performance multi-chip modules. The present technique is also highly relevant to wafer-on-wafer bonding, a process that is instrumental in the vertical integration of memory and storage devices, thereby enabling the production of high-density configurations that are essential for advanced computing applications. Furthermore, the present technique is adeptly suited for the manufacturing of three-dimensional dynamic random-access memory (3D-DRAM) and 3D NAND flash memory, where it facilitates the vertical stacking and connection of memory cells, resulting in substantial improvements in data storage capacity and access speeds. The versatility of the present technique allows for its application across various semiconductor fabrication processes, thereby addressing the growing demand for miniaturization and enhanced performance in the electronics industry.

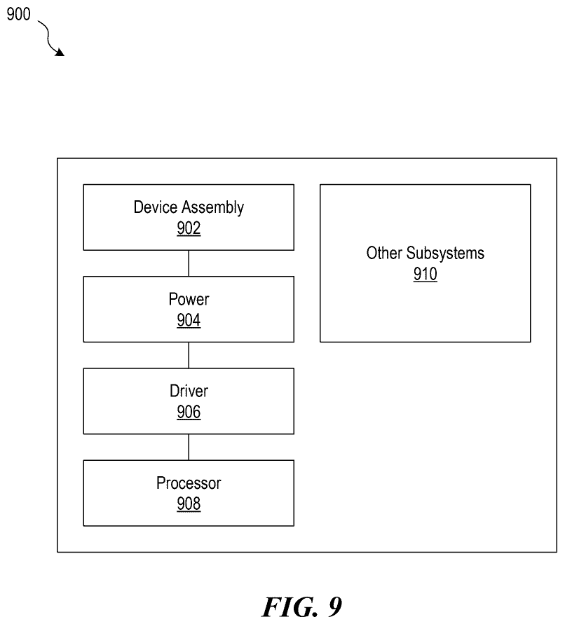

Any one of the semiconductor devices and semiconductor device assemblies described above with reference to FIGS. 1 to 8 can be incorporated into any of a myriad of larger and/or more complex systems, a representative example of which is system 900 shown schematically in FIG. 9. The system 900 can include a semiconductor device assembly (e.g., or a discrete semiconductor device) 902, a power source 904, a driver 906, a processor 908, and/or other subsystems or components 910. The semiconductor device assembly 902 can include features generally similar to those of the wafer bonding and debonding processes described above with reference to FIGS. 1 to 8. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 900 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor wafer, comprising:
a first dielectric layer disposed on top of the semiconductor wafer, the first dielectric layer having a first frontside surface;
a second dielectric layer embedded in the first dielectric layer, the second dielectric layer containing moisture and having a second frontside surface horizontally aligned with the first frontside surface; and
oxygen covalent dangling bonds and hydroxide dangling bonds disposed on the first frontside surface and the second frontside surface.

2. The semiconductor wafer of claim 1, wherein the oxygen covalent dangling bonds have a higher density than the hydroxide dangling bonds on the first frontside surface.

3. The semiconductor wafer of claim 1, wherein the hydroxide dangling bonds have a higher density than the oxygen covalent dangling bonds on the second frontside surface.

4. The semiconductor wafer of claim 1, wherein the first dielectric layer is made of materials comprising silicon dioxide (SiO₂).

5. The semiconductor wafer of claim 1, wherein the second dielectric layer is made of material comprising tetraethyl orthosilicate (TEOS), silicon carbon nitride (SiCN), or a combination thereof.

6. The semiconductor wafer of claim 1, wherein the oxygen covalent dangling bonds have a higher bond energy than the hydroxide dangling bonds.

7. The semiconductor wafer of claim 1, wherein a first ratio of density of the oxygen covalent dangling bonds to density of the hydroxide dangling bonds is proportional to a second ratio of volume of the first dielectric layer to volume of the second dielectric layer.

8. The semiconductor wafer of claim 1, wherein the second dielectric layer has a thickness equal to or less than the first dielectric layer.

9. The semiconductor wafer of claim 1, wherein the first dielectric layer has a thickness ranging from 10 nm to 10 μm.

10. The semiconductor wafer of claim 1, wherein the second dielectric layer extends to an edge of the semiconductor wafer.

11. A semiconductor wafer, comprising:
a first dielectric layer disposed on top of the semiconductor wafer, the first dielectric layer having a frontside surface;
a second dielectric layer disposed underneath the first dielectric layer, the second dielectric layer containing moisture; and
oxygen covalent dangling bonds and hydroxide dangling bonds disposed on the frontside surface.

12. The semiconductor wafer of claim 11, wherein a first ratio of a first density of the oxygen covalent dangling bonds to a second density of the hydroxide dangling bonds is proportional to a second ratio of a first thickness of the first dielectric layer to a second thickness of the second dielectric layer.

13. The semiconductor wafer of claim 11, wherein the first dielectric layer is made of materials comprising silicon dioxide (SiO₂).

14. The semiconductor wafer of claim 11, wherein the second dielectric layer is made of material comprising tetraethyl orthosilicate (TEOS), silicon carbon nitride (SiCN), or a combination thereof.

15. The semiconductor wafer of claim 11, wherein the semiconductor wafer is a device wafer or a carrier wafer.

16. A method of debonding semiconductor wafers, comprising:
providing one or more semiconductor device wafers and a carrier wafer, at least one of the one or more semiconductor device wafers and the carrier wafer having a frontside surface comprising at least one of oxygen covalent dangling bonds and hydroxide dangling bonds;
bonding the one or more semiconductor device wafers to the carrier wafer by forming dielectric-dielectric bonds at a bonding interface between the one or more semiconductor device wafers and the carrier wafer;
weakening the dielectric-dielectric bonds by introducing moisture to the bonding interface; and
debonding the one or more semiconductor device wafers from the carrier wafer.

17. The method of debonding semiconductor wafers of claim 16, wherein weakening the dielectric-dielectric bonds comprises converting oxygen covalent bonds into hydroxide ionic bonds at the bonding interface.

18. The method of debonding semiconductor wafers of claim 16, wherein providing one or more semiconductor device wafers and a carrier wafer comprises forming a first dielectric layer disposed on top of a semiconductor wafer of the one or more semiconductor wafers, the first dielectric layer having a first frontside surface, and forming a second dielectric layer embedded in the first dielectric layer, the second dielectric layer containing moisture and having a second frontside surface horizontally aligned with the first frontside surface.

19. The method of debonding semiconductor wafers of claim 16, wherein providing one or more semiconductor device wafers and a carrier wafer comprises forming a first dielectric layer disposed on top of a semiconductor wafer of the one or more semiconductor wafers, and forming a second dielectric layer disposed underneath the first dielectric layer, the second dielectric layer containing moisture.

20. The method of debonding semiconductor wafers of claim 17, wherein debonding the one or more semiconductor device wafers from the carrier wafer comprises breaking the hydroxide ionic bonds at the bonding interface.
